(19) United States
(12) Patent Application Publication
(10) Pub. No.: US 2010/0315878 A1
(43) Pub. Date: Dec. 16, 2010

(54) SEMICONDUCTOR MEMORY DEVICE INCLUDING MEMORY CELL WITH CHARGE ACCUMULATION LAYER

(76) Inventor: Toshiaki EDAHIRO, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/813,089

(22) Filed: Jun. 10, 2010

(30) Foreign Application Priority Data
Jun. 15, 2009 (JP) 2009-142141

(51) Int. Cl. G11C 16/06

(52) U.S. Cl. 365/185.21

(57) ABSTRACT

According to one embodiment, a semiconductor memory device includes a memory cell, a bit line, a sense amplifier, a first MOS transistor, and a current source circuit. The bit line transfers data read from the memory cell and/or data to be written to the memory cell. The sense amplifier charges the bit line during a data read and a data write. The first MOS transistor connects the bit line and the sense amplifier together. The current source circuit supplies a constant current to a gate of the first MOS transistor to charge the gate during a data write and/or a data read.

### CROSS-REFERENCE TO RELATED APPLICATIONS

This application is based upon and claims the benefit of priority from Japanese Patent Application No. 2009-142141, filed Jun. 15, 2009; the entire contents of which are incorporated herein by reference.

### FIELD

Embodiments described herein relate generally to a semiconductor device including a memory cell with a charge accumulation layer.

### BACKGROUND

NAND flash memories are conventionally known as nonvolatile semiconductor memories. For NAND flash memories, a technique used for a data write operation is known. The technique involves charging bit lines to which memory cells to be subjected to no data write are connected, up to a predetermined voltage, thus floating the channel of a NAND string. Then, the potential of the channel is increased by coupling with a gate electrode to inhibit charges from being injected into the memory cells. Such a technique is disclosed in, for example, Jpn. Pat. Appln. KOKAI Publication No. 10-283788.

### BRIEF DESCRIPTION OF THE DRAWINGS

FIG. 1 is a block diagram of a NAND flash memory according to a first embodiment;

FIG. 2 is a graph showing the threshold distribution of a memory cell according to the first embodiment;

FIG. 3 is a graph showing the temperature characteristics of a drain current flowing through a

MOS transistor according to the first embodiment;

FIG. 4 is a circuit diagram of a bit line driver according to the first embodiment;

FIG. 5 is a graph showing the temperature characteristics of output currents from a current source and a constant current circuit according to the first embodiment;

FIG. 6 is a timing chart of various signals provided during a data write according to the first embodiment;

FIG. 7 is a circuit diagram of a bit line driver;

FIG. 8 to FIG. 10 are graphs showing temporal variations in Vblc, Vbl, and Icc, respectively;

FIG. 11 is a circuit diagram showing a partial region of a NAND flash memory according to a second embodiment;

FIG. 12 is a circuit diagram of a voltage generator and a detector according to the second embodiment; and

FIG. 13 is a circuit diagram of a sense amplifier according to the first and second embodiments.

### DETAILED DESCRIPTION

In general, according to one embodiment, a semiconductor memory device includes: a memory cell; a bit line; a sense amplifier; a first MOS transistor; and a current source circuit. The memory cell is capable of holding data. The bit line transfers data read from the memory cell and/or data to be written to the memory cell. The sense amplifier charges the bit line during a data read and a data write. The first MOS transistor connects the bit line and the sense amplifier together. The current source circuit supplies a constant current to a gate of the first MOS transistor to charge the gate during a data write and/or a data read.

### First Embodiment

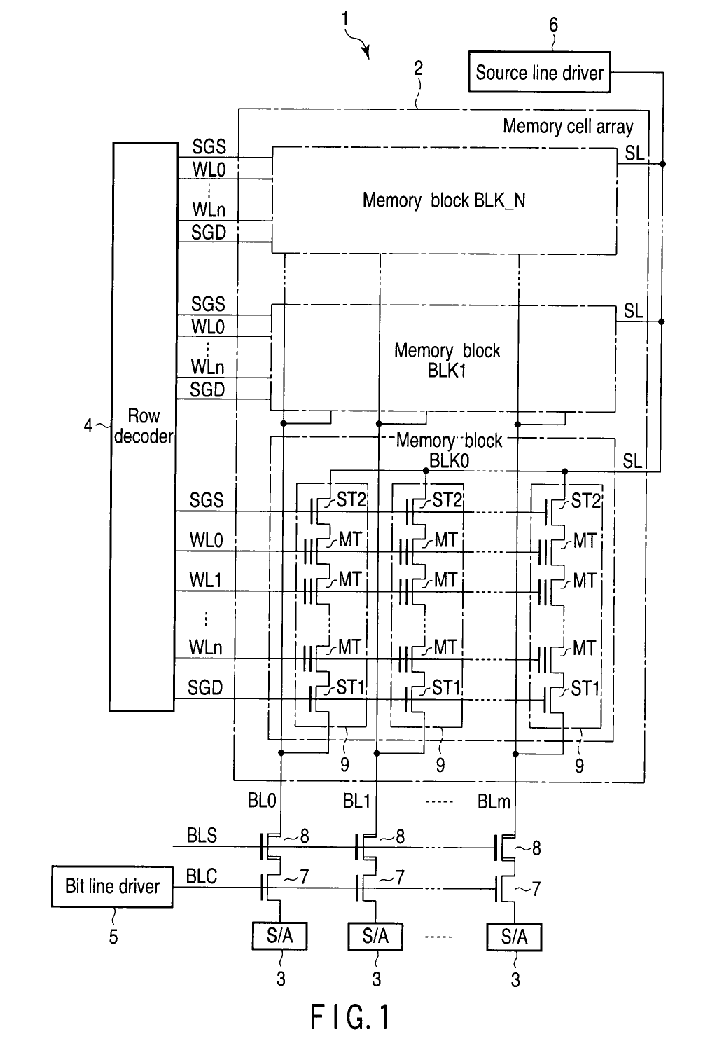

A semiconductor memory device according to a first embodiment will be described taking a NAND flash memory as an example. FIG. 1 is a block diagram of the NAND flash memory according to the present embodiment.

### <Configuration of the NAND Flash Memory>

As shown in FIG. 1, the NAND flash memory 1 includes a memory cell array 2, a sense amplifier 3, a row decoder 4, a bit line driver 5, a source line driver 6, and MOS transistors 7 and 8.

First, the memory cell array 2 will be described. The memory cell array 2 includes a plurality of ((N+1); N is a natural number equal to or larger than one) memory blocks BLK0 to BLKN. The memory blocks BLK0 to BLKN are hereinafter simply referred to as the memory blocks BLK if the memory blocks BLK0 to BLKN are not distinguished from one another. The number of memory blocks BLK provided may be one. Each of the memory blocks BLK includes (m+1) ((m+1) is a natural number equal to or larger than one) NAND strings 9.

Each of the NAND strings 9 includes (n+1) ((n+1) is a natural number which is equal to or larger than 2 and which is not limited and may be, for example, 8, 16, 32, or 64) memory cell transistors MT and selection transistors ST1 and ST2. The memory cell transistor MT has a stack gate structure including a charge accumulation layer (for example, a floating gate) formed on a semiconductor substrate with a gate insulating film interposed therebetween, and a control gate formed on the charge accumulation layer with an inter-gate insulating film interposed therebetween. The adjacent memory cell transistors MT share a source and a drain. The group of memory cell transistors MT is arranged between the selected transistors ST1 and ST2 so that current paths in the memory cell transistors MT are connected together in series. A drain of one of the series connected memory cell transistors MT located at one end of the group of memory cell transistors MT is connected to a source of the selection transistor ST1. A source of one of the series connected memory cell transistors MT located at the other end is connected to a drain of the selection transistor ST2.

In the memory blocks BLK, the control gates of the memory cell transistors MT on the same row are all connected to one of word lines WL0 to WLn. Gates of the selection transistors ST1 on the same row are connected to a selection gate line SGD. Gates of the selection transistors ST2 on the same row are connected to a selection gate line SGS. For simplification of description, the word lines WL0 to WLn are hereinafter sometimes simply referred to as the word lines WL. Sources of the selection transistors ST2 are all connected to a source line SL.

In the memory cell array 2 configured as described above, drains of the selection transistors ST1 in the NAND strings 9 on the same column are connected to the same one of bit lines BL0 to BLm. The bit lines BL0 to BLm are also hereinafter sometimes simply referred to as the bit lines BL. That is, the bit line BL connects all the NAND strings 9 in the same memory block BLK together. On the other hand, the word lines WL and the selection gate lines SGD and SGS connect all the NAND strings 9 in the same memory block BLK together. Furthermore, the NAND strings 9 included in the memory cell array 2 are all connected to the same source line SL.

Furthermore, data is written at a time to the plurality of memory cell transistors MT connected to the same word line WL. This unit is called a page. Moreover, data is erased from all the NAND strings 9 in the same memory block BLK at a time. That is, the memory block BLK is an erase unit.

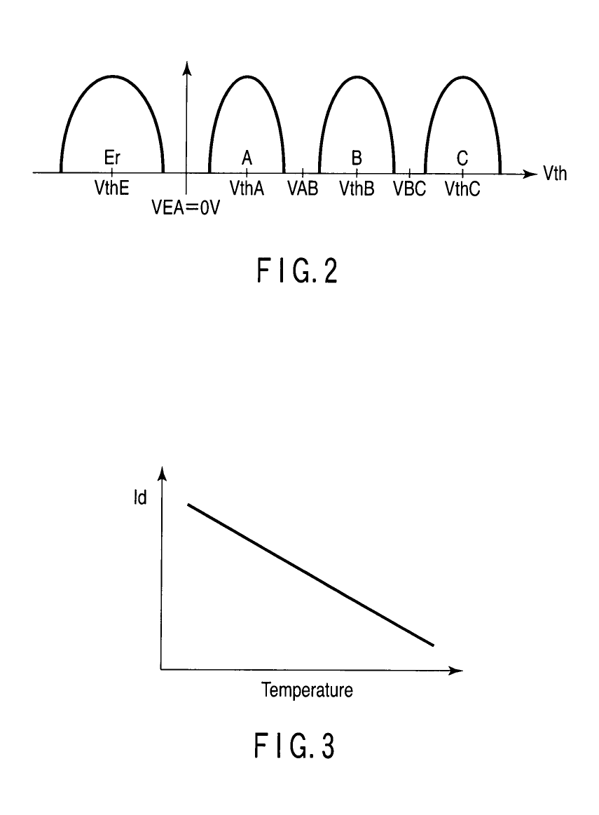

Now, the threshold distribution of the memory cell transistor MT will be described with reference to FIG. 2. FIG. 2 is a graph in which the axis of abscissas indicates a threshold voltage Vth, and the axis of ordinate indicates the existence probability of the memory cell transistor MT.

As shown in FIG. 2, each memory cell transistor MT can hold 4-level data (2-bit data). That is, the memory cell transistor MT can be set to one of four states (four types of data); an erase level (“Er”), an A level, a B level, and a C level, which are arranged in order of increasing threshold voltage Vth. The threshold voltage VthE for the erase level is such that VthE<VEA. The threshold voltage VthA for the A level is such that VEA<VthA<VAB. The threshold voltage VthB for the B level is such that VAB<VthB<VBC. The threshold voltage VthC for the C level is such that VBC<VthC. For example, the voltage VEA is 0 V. However, VAB may be 0 V. Furthermore, the data that can be held by the memory cell transistor MT is not limited to the 4 levels. For example, the data may have 2 levels (1-bit data), 8 levels (3-bit data), or 16 levels (4-bit data).

The description of the configuration of the flash memory 1 will be continued again with reference to FIG. 1. For a data read, the sense amplifier 3 senses and amplifies data read from each memory cell transistor MT onto the corresponding bit line BL. At this time, the sense amplifier 3 senses a current flowing through the bit line BL to determine the data type for all the bit lines BL at a time. Instead of the current, a voltage may be sensed. Furthermore, for a data write, the sense amplifier transfers write data to the bit line BL.

For a data write operation, a data read operation, and a data erase operation, the row decoder 4 selects the selection gate lines SGD and SGS and word line WL connected to one of the memory blocks BLK based on an externally provided row address RA. The row decoder 4 then applies a voltage to the selection gate lines SGD, SGS and word line WL.

The source line driver 6 applies a voltage to the source line SL.

Each of the MOS transistors 7 connects the sense amplifier 3 and the bit line BL together via the current path in the MOS transistor 8. That is, one end of the current path in the MOS transistor 7 is connected to the sense amplifier 3. The other end is connected to one end of the current path in the MOS transistor 8. A signal BLC is applied to a gate of the MOS transistor 7. The MOS transistor 7 is, for example, an n-channel MOS transistor with a lower withstand voltage than the MOS transistor 8. The MOS transistor 7 has a thinner gate insulating film than the MOS transistor 8. FIG. 3 is a graph showing the temperature characteristics of a drain current Id of the MOS transistor 7. In FIG. 3, the axis of ordinate indicates the drain current Id, and the axis of abscissas indicates temperature. In particular, FIG. 3 shows that the conditions other than temperature are constant. As shown in FIG. 3, the drain current Id decreases consistently with temperature. That is, the drain current Id offers negative temperature characteristics. However, FIG. 3 is only illustrative. It is generally only necessarily that the drain current Id decreases with increasing temperature. The shape of the graph is not limited to the one shown in FIG. 3.

The description will be continued again with reference to FIG. 1. In each of the MOS transistors 8, one end of the current path is connected to the other end of the current path in the corresponding MOS transistor 7. The other end of the current path in the MOS transistor 8 is connected to the corresponding bit line BL. A signal BLS is applied to a gate of the MOS transistor 8. The signal BLS is provided by a control circuit (not shown in the drawings). The MOS transistor 8 is, for example, an n-channel MOS transistor with a high withstand voltage. Both the MOS transistors 7 and 8 provide a function for connecting the bit line BL and the sense amplifier 3 together. However, the MOS transistor 7 further provides a function to control the potential of the bit line BL using the signal BLC.

The bit line driver 5 generates and supplies a signal BLC to the gate of the MOS transistor 7. For a data write and a data read, the potential of the bit line BL is controlled by the potential of the signal BLC.

### <Details of the Bit Line Driver 5>

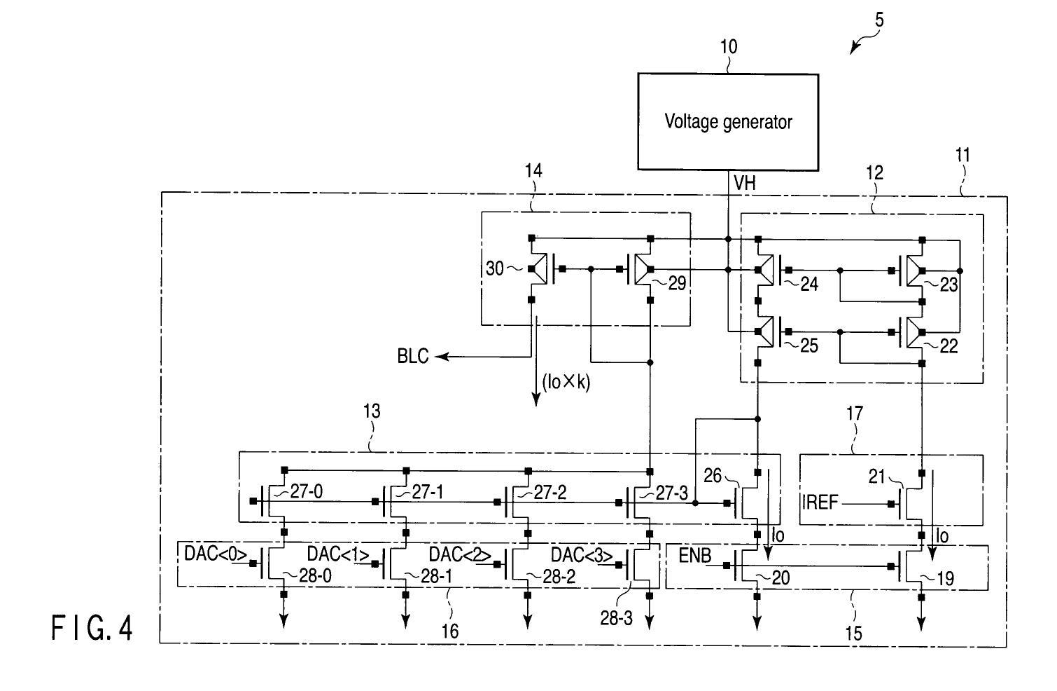

Now, the bit line driver 5 will be described in detail with reference to FIG. 4. FIG. 4 is a circuit diagram of the bit line driver 5.

As shown in FIG. 4, roughly speaking, the bit line driver 5 includes a voltage generator 10, a constant current circuit 11. The voltage generator 10 generates and outputs a voltage VH (=power supply voltage VDD+threshold Vth of the MOS transistor 7+about α).

Roughly speaking, the constant current circuit 11 includes a first current mirror circuit to a third current mirror circuit 12 to 14, a first switch circuit 15 and a second switch circuit 16, and a current generator 17.

The first switch circuit 15 includes n-channel MOS transistors 19 and 20. Each of sources of the MOS transistors 19 and 20 is grounded. A signal ENB is applied to gates of both the MOS transistors 19 and 20. The signal ENB is provided by a control circuit (not shown in the drawings). The application of the signal ENB turns on the MOS transistors 19 and 20, thus activating the bit line driver 5.

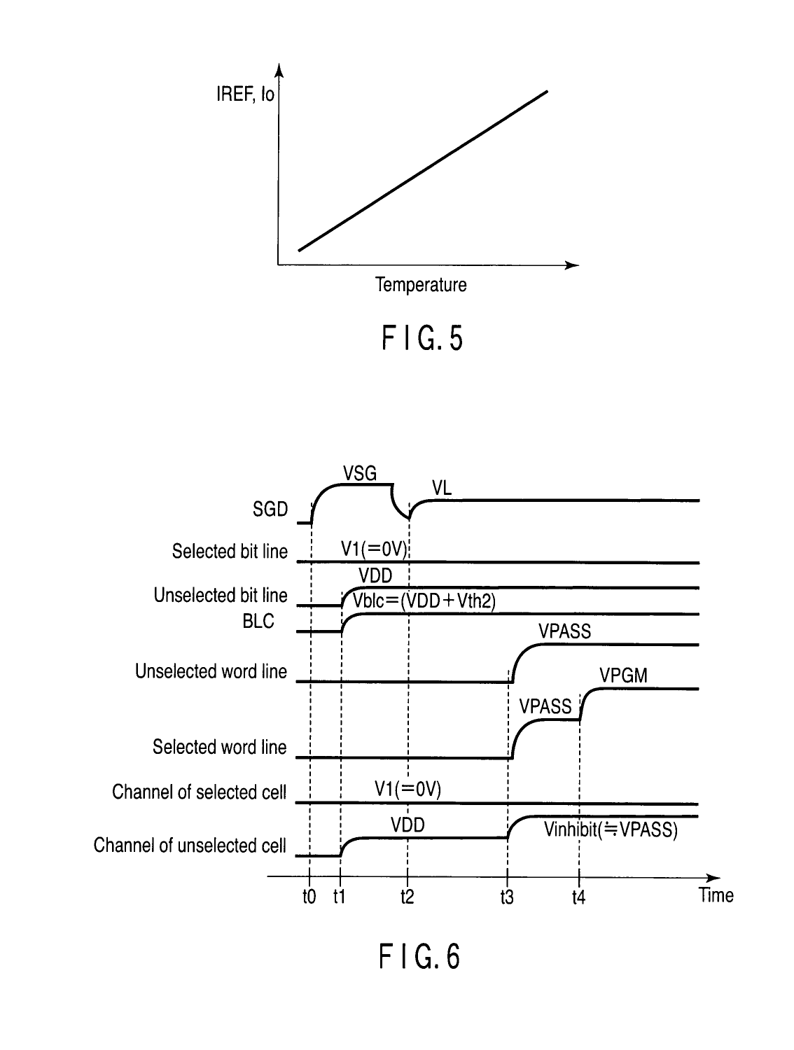

The current generator 17 includes an n-channel MOS transistor and a constant current source (not shown in the drawings). A source of the MOS transistor 21 is connected to a drain of the MOS transistor 19. The constant current source generates a constant current IREF with temperature characteristic opposite to those of the drain current flowing through the MOS transistor 7, specifically, positive temperature characteristics. The constant current source then supplies the constant current IREF to the gate of the MOS transistor 21. Thus, a drain current Io of the MOS transistor 21 has positive temperature characteristics. FIG. 5 is a graph showing the temperature characteristics of the currents IREF and Io. In FIG. 5, the axis of ordinate indicates the currents IREF and Io, and the axis of abscissas indicates the temperature. In particular, FIG. 5 shows that the conditions other than temperature are constant. The magnitudes of the currents IREF and Io increase consistently with the temperature. Of course, FIG. 5 is also only illustrative. It is generally only necessary that the magnitudes of the currents IREF and Io increase consistently with the temperature. The shape of the graph is not limited to the one shown in FIG. 5.

The first current mirror circuit 12 includes p-channel MOS transistors 22 to 25. The voltage VH generated by the voltage generator 10 is applied to back gates of the MOS transistors 22 to 25. A drain of the MOS transistor 22 is connected to a gate of the MOS transistor 22 and to a drain of the MOS transistor 21. A drain of the MOS transistor 23 is connected to a gate of the MOS transistor 23 and to a source of the MOS transistor 22. The voltage VH is applied to a source of the MOS transistor 23. A gate of the MOS transistor 24 is connected to the gate of the MOS transistor 23. The voltage VH is applied to a source of the MOS transistor 24. A gate of the MOS transistor 25 is connected to the gate of the MOS transistor 22. A source of the MOS transistor 25 is connected to a drain of the MOS transistor 24.

The second current mirror circuit 13 includes n-channel MOS transistors 26 and 27-0 to 27-3. Gates of the n-channel MOS transistors 26 and 27-0 to 27-3 are connected together. A gate and a drain of the MOS transistor 26 are connected to a drain of the MOS transistor 25. Thus, the amount of a drain current flowing through the MOS transistor 26 is equal to that of a drain current flowing through the MOS transistor 21, Io. Drains of the MOS transistors 27-0 to 27-3 are connected together. The MOS transistors 27-0 to 27-3 are hereinafter collectively referred to as the MOS transistors 27 if the MOS transistors 27-0 to 27-3 are not distinguished from one another.

The second switch circuit 16 includes n-channel MOS transistors 28-0 to 28-3 provided in association with the MOS transistors 27-0 to 27-3, respectively. Drains of the MOS transistors 28-0 to 28-3 are connected to sources of the MOS transistors 27-0 to 27-3, respectively. Sources of the MOS transistors 28-0 to 28-3 are grounded. Signals DAC<0> to DAC<3> are input to gates of the MOS transistors 28-0 to 28-3, respectively. The signals DAC<0> to DAC<3>are provided by, for example, a control circuit (not shown in the drawings). The MOS transistors 28-0 to 28-3 are hereinafter collectively referred to as the MOS transistors 28 if the MOS transistors 28-0 to 28-3 are not distinguished from one another.

The third current mirror circuit 14 includes p-channel MOS transistors 29 and 30. The voltage VH generated by the voltage generator 10 is applied to back gates of the MOS transistors 29 and 30. A gate and a drain of the MOS transistor 29 are connected to a drain of the MOS transistor 27. The voltage VH is applied to a source of the MOS transistor 29. A gate of the MOS transistor 30 is connected to the gate of the MOS transistor 29. The voltage VH is applied to a source of the MOS transistor 30.

In the above-described configuration, a signal from the drain of the MOS transistor 30 is applied to the gate of the MOS transistor 7 as the signal BLC. The amount of current Iblc of the signal BLC can be varied depending on the number of MOS transistors 28 to be turned on. When the number of MOS transistors 28 to be turned on is defined as (k) ((k) is a natural number equal to or larger than one), Iblc=(Io*k). The current thus have positive temperature characteristics as is the case with FIG. 5. Which of the MOS transistors 28-0 to 28-3 is to be turned on can be controlled by the signals DAC<0> to DAC<3>.

### <Operation of the NAND Flash Memory 1>

Now, the operation of the NAND flash memory configured as described above will be described.

### <Data Write Operation>

First, a data write operation will be described with reference to FIG. 6. FIG. 6 is a timing chart showing variations in the potentials of a selection gate line SGD, a selected bit line, an unselected bit line, the signal BLC, an unselected word line, a selected word line, the channels of memory cell transistors MT connected to the selected bit line, and the channel of memory cell transistor MT connected to an unselected bit line, in data write operation. The selected bit line refers to a bit line connecting to a memory cell transistor MT (sometimes referred to as a selected cell) with its threshold level to be increased by injecting charges into the charge accumulation layer. The unselected bit line refers to a bit line connecting to a memory cell transistor MT (sometimes referred to as an unselected cell) with its threshold level unchanged, because of avoidance of injection of charges into the charge accumulation layer.

As described above, data is written at a time to all the memory cell transistors MT connected to the same word line (one page). Furthermore, the data write is sequentially carried out on the memory cell transistors MT in the memory block 9 in an erased state, in order of increasing distance to the selection gate line SGS.

In the data write, the row decoder 4 selects the selection gate line SGD in any of the memory blocks BLK and applies a voltage VSG (=VDD+Vth1; Vth1 denotes the threshold voltage of the selection transistor ST1) to the selected selection gate line SGD (time t0).

Furthermore, the bit line driver 5 generates and supplies a signal BLC to the gate of the MOS transistor 7 (time t1). The potential of the signal BLC is about (VDD+Vth2). Vth2 denotes the threshold voltage of the MOS transistor 7. Thus, the MOS transistor 7 is turned on. The application of the signal BLS also allows the MOS transistor 8 to be turned on.

Furthermore, the sense amplifier 3 applies a voltage corresponding to write data to the bit line BL via the transistors 7 and 8. Specifically, a voltage V1 (for example, 0 V) is applied to the selected bit line. The voltage VDD (for example, 2 V) is applied to the unselected bit line (time t1). The potential on the unselected bit line is determined by the MOS transistor 7 (in other words, by the signal BLC).

As a result, the voltage V1 is transferred to the channel of the selected cell. The voltage VDD is transferred to the channel of the unselected cell. The selection gate line SGS is at 0 V. The selection transistor ST2 is off during a write period.

Then, the row decoder 4 changes the voltage of the selection gate line SGD from the voltage VSG to a voltage VL (time t2). The voltage VL is, for example, lower than the voltage VDD, and prevents the selection transistor ST1 from transferring the voltage applied to the unselected bit line. As a result, the selection transistor ST1 connected to the unselected bit line is set to a cutoff state. Thus, the channels of all the memory cell transistors MT included in the NAND string connected to the unselected bit line are electrically separated from the unselected bit line and made to float electrically. On the other hand, the selection transistor ST1 connected to the selected bit line remains on. Thus, the channels of all the memory cell transistors MT included in the NAND cells connected to the selected bit line remain electrically connected to the selected bit line. The value of the voltage of the channels is V1.

Thereafter, the row decoder 4 applies a voltage VPASS to all the word lines WL0 to WLn in the selected memory block BLK (time t3). The application of the voltage VPASS allows all the memory transistors MT to be turned on regardless the data held by the memory cell transistor. Thus, channels are formed.

Then, the row decoder 4 selects any of the word lines WL, and applies a program voltage VPGM to the selected word line. Furthermore, the row decoder 4 applies the voltage VPASS to the unselected word line (time t4).

The application of the program voltage VPGM allows the data in the selected cell to be programmed. That is, in the selected cell, the potential on the word line WL is set to VPGM, and the potential Vch of the channel is set to 0 V. Thus, a large potential difference is applied to between the control gate and the channel. As a result, FN (Fowler-Nordheim) tunneling occurs to cause charges to be injected into the charge accumulation layer.

On the other hand, in the unselected cell, the channel is floating electrically. Thus, the potential Vch of the channel is coupled with the program voltage VPGM applied to the selected word line and the voltage VPASS applied to the unselected word line, to increase up to a write inhibition voltage Vinhibit (see time t3 and later). The value of the write inhibition voltage Vinhibit is substantially equal to VPASS. As a result, the value of the potential difference between the control gate and the channel is insufficient for FN tunneling. This prevents charges from being injected into the charge accumulation layer. Even if charges are injected into the charge accumulation layer, the threshold is prevented from varying enough to program the data.

The data write operation is performed as described above.

### <Data Read Operation>

Now, a data read operation will be described in brief. As described above, a data read is also carried out, at a time, on all the memory cell transistors MT connected to the same word line (one page), simultaneously.

For a data read, the row decoder 4 selects the selection gate line SGD in one of the memory blocks, and applies, for example, a voltage V2 (≧VDD+Vth1) to the selected selection gate line SGD. Thus, the selection transistor ST1 is turned on. Similarly, the selection transistor ST2 is also turned on.

Furthermore, the bit line driver 5 generates a signal BLC, and supplies the signal BLC to the MOS transistor 7. The potential of the signal BLC is about (0.7+Vth2). Thus, the MOS transistor 7 is turned on. The application of the signal BLS allows the MOS transistor 8 to be turned on.

Furthermore, the sense amplifier 3 precharges the bit line BL via the current paths in the MOS transistors 7 and 8. The precharge potential is, for example, 0.7 V. This value is determined by the MOS transistor 7 (in other words, the signal BLC).

Moreover, the row decoder 4 applies a voltage VCGR to the selected word line and applies a voltage VREAD to unselected word lines in a selected memory block BLK. The voltage VREAD allows all the memory cell transistors MT to be turned on regardless of the data held by the memory cell transistor. The voltage VCGR corresponds to data to be read and may be equal to, for example, VEA, VAB, or VBC, described with reference to FIG. 2.

As a result, when the memory cell transistor MT connected to the selected word line is turned on, a current flows through the bit line BL toward the source line SL. On the other hand, when the memory cell transistor MT is off, no current flows through the bit line BL. The sense amplifier 3 senses the current to determine the data type.

### <Effects>

As described above, a certain technique for NAND flash memories allows the channel of the NAND string connected to the unselected bit line to float during a data write. This technique is called self boosting. According to the technique, the potential of the floating channel is increased by coupling with the gate. This inhibits charges from being injected into the charge accumulation layer in the unselected cell. To cut off the selection transistor ST1 connected to the unselected bit line, the technique needs to charge the potential on the unselected bit line to a high potential such as VDD.

Then, a large peak current follows because a large number of memory cell transistors are connected to each word line WL. The large peak current significantly reduces the power supply voltage, thus affecting the operation of other simultaneously operating circuits. Hence, desirably, the peak current is as small as possible and is generally constant even if the temperature or the power supply voltage varies. This also applies to reads.

In this regard, the semiconductor memory device according to the present embodiment enables a reduction in the adverse effect of the peak current associated with charging of the bit line. This allows the operational stability of the semiconductor memory device to be improved. This effect will be described below in detail.

In order to charge the bit line to the VDD level, the level of the signal BLC needs to be set at least to (VDD+Vth2). A charging speed for the bit line BL is determined by the resistance and capacitance of the bit line BL, the driving force of the MOS transistor 7, and the speed at which the potential of the signal BLC is increased to (VDD+Vth2).

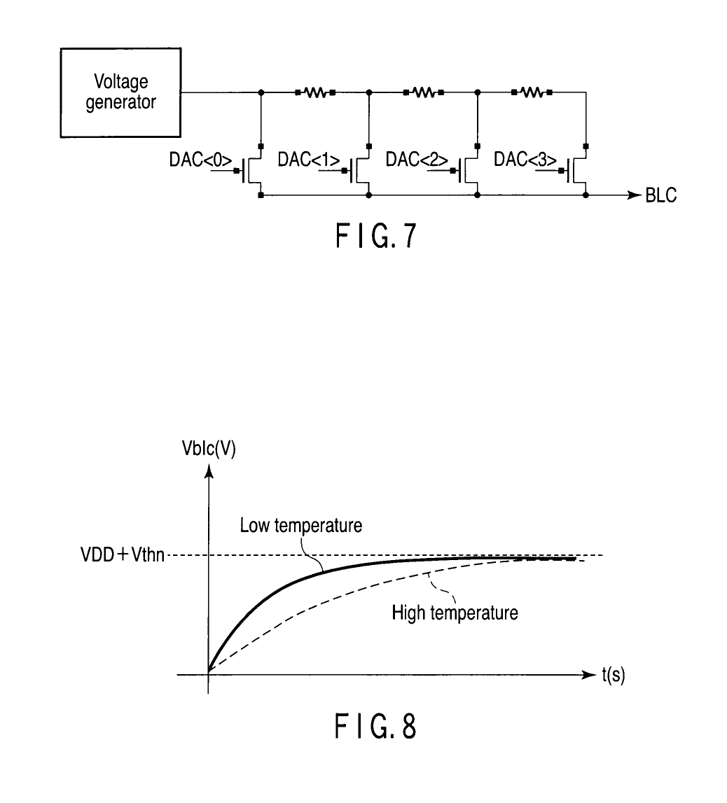

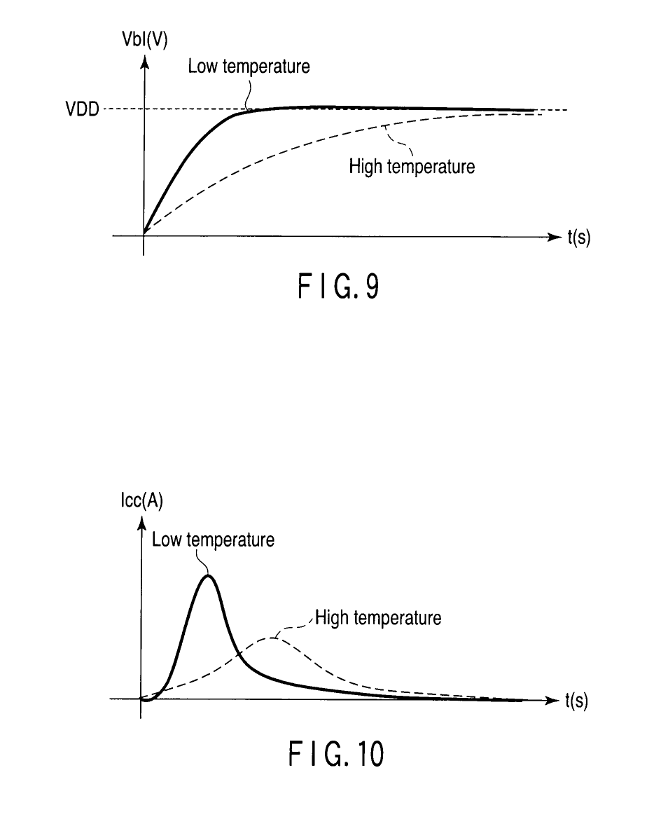

FIG. 7 is a circuit diagram showing a referential example of a bit line driver. As shown in FIG. 7, to set a ramp rate for the potential of the signal BLC, it is possible to connect a plurality of resistance elements together in series and to select any of the resistance elements using a switch (illustrated MOS transistor). However, the resistance element is generally formed of an impurity diffusion layer formed in a semiconductor substrate, a polycrystalline silicon layer, or the like. Thus, the resistance value tends to increase consistently with the temperature. Hence, as seen in a graph in FIG. 8 showing a temporal variation in voltage Vblc, the speed at which Vblc increase up to (VDD+Vth2) decreases with increasing temperature. Furthermore, in general, the amount of a drain current of a MOS transistor increases with decreasing temperature. Thus, when the ramp rate of the potential of the signal BLC is controlled by the configuration shown in FIG. 7, the resulting potential Vbl and current Icc on the bit line BL are as shown in FIG. 9 and FIG. 10, respectively. That is, at lower temperatures, the ramp rate of Vbl and the amount of the current increase. Hence, the charging speed for the bit line BL increases, contributing to an increase in peak current.

In contrast, in the configuration according to the present embodiment, the current source (current IREF) with positive temperature characteristics produces a constant current Io, which is copied by the current mirror circuit. Then, the amount of current is adjusted using the signals DAC<0> to DAC<3>, to charge BLC up to the level (VDD+Vth2).

The current IREF increases and decreases consistently with the temperature because of the positive temperature characteristics of the current IREF. That is, the current IREF has temperature characteristics opposite to those of a drain current of an n-channel MOS transistor. Thus, IREF can suppress (offset) the temperature characteristics of the MOS transistor.

As a result, the dependence of the charging speed for the bit line BL on the temperature can be reduced, thus suppressing a significant variation in peak current depending on the temperature. In other words, at low temperature, the peak current is prevented from increasing significantly (see FIG. 10) and can be reduced. Therefore, the adverse effect of a variation in peak current on peripheral circuits can be suppressed. Furthermore, the operational stability of the NAND flash memory can be improved.

The current supplied by the constant current circuit 11 need not necessarily have temperature characteristics opposite to those of the MOS transistor 7. Even in this case, a certain constant effect is exerted. When a resistance element is used as shown in FIG. 7, if there is a large potential difference across the resistance element, a large current flows through the interconnection for BLC. Thus, BLC rises at high speed to significantly vary the current flowing through the MOS transistor 7. This increases the peak current for bit line charging. On the other hand, when the level of BLC increases and the potential difference is reduced, the amount of current flowing through the interconnection for BLC decreases. This results in degraded controllability such as a decrease in the ramp rate of the BLC. However, when a current source is used to charge BLC as is the case with the present embodiment, the gradient of BLC can be made almost constant. Therefore, a variation in peak current can be more easily suppressed.

### Second Embodiment

A semiconductor memory device according to a second embodiment will be described. The present embodiment corresponds to the method according to the above-described first embodiment which involves a configuration for detecting a current Iblc flowing through a bit line BL so as to allow the current to be properly controlled. Only differences from the above-described first embodiment will be described below.

### <Configuration of the NAND Flash Memory>

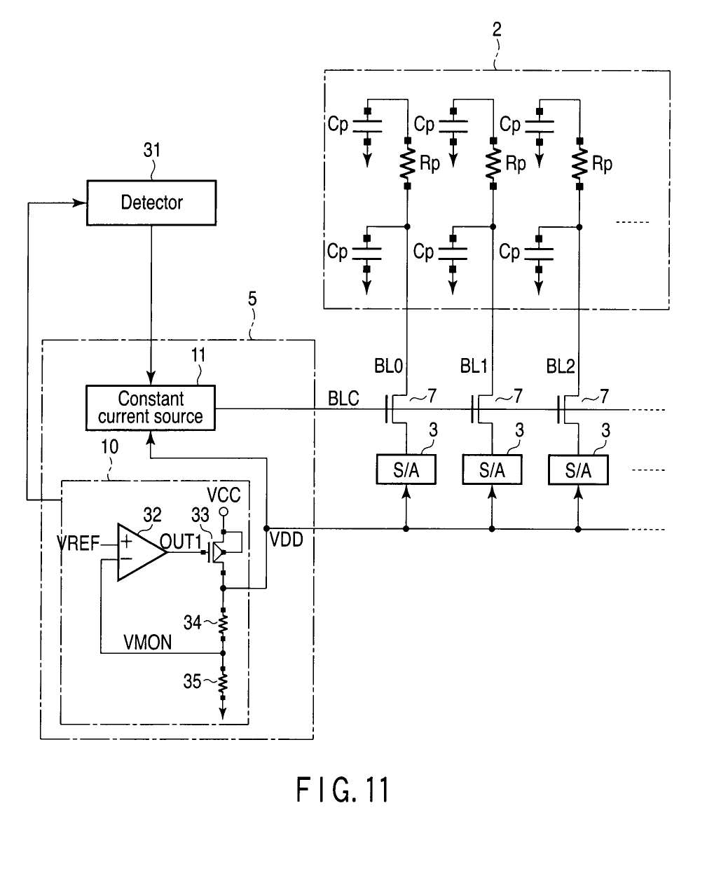

FIG. 11 is a circuit diagram of a partial region of a NAND flash memory according to the present embodiment. As shown in FIG. 11, a configuration according to the present embodiment corresponds to the configuration in FIG. 1 described in the first embodiment and which further includes a detector 31. The detector 31 detects a current flowing through the bit line BL being charged.

A voltage generator 10 in a bit line driver 5 includes an operational amplifier 32, a p-channel MOS transistor 33, and resistance elements 34 and 35.

A source of the MOS transistor 33 is connected to an external power supply Vcc. A drain of the MOS transistor 33 is connected to one end of the resistance element 34. The other end of the resistance element 34 is connected to one end of the resistance element 35. The other end of the resistance element 35 is grounded. The operational amplifier 32 compares a reference voltage VREF with the voltage VMON of the connection node between the other end of the resistance element 34 and the one end of the resistance element 35. The operational amplifier 32 then outputs the result of the comparison through an output node OUT1 to control the gate potential of the MOS transistor 33. The voltage of the connection node between the drain of the MOS transistor 33 and the one end of the resistance element 34 is output as a voltage VDD.

The voltage VDD generated by the voltage generator 10 is used as a power supply voltage for a sense amplifier 3. That is, to charge the bit line BL to VDD, the sense amplifier 3 transfers the voltage VDD provided by the voltage generator 10, to the bit line BL.

The detector 31 detects a drain current of the MOS transistor 33 in the voltage generator 10 configured as described above to detect a current required to charge the bit line BL.

### <Configuration of the Detector 31>

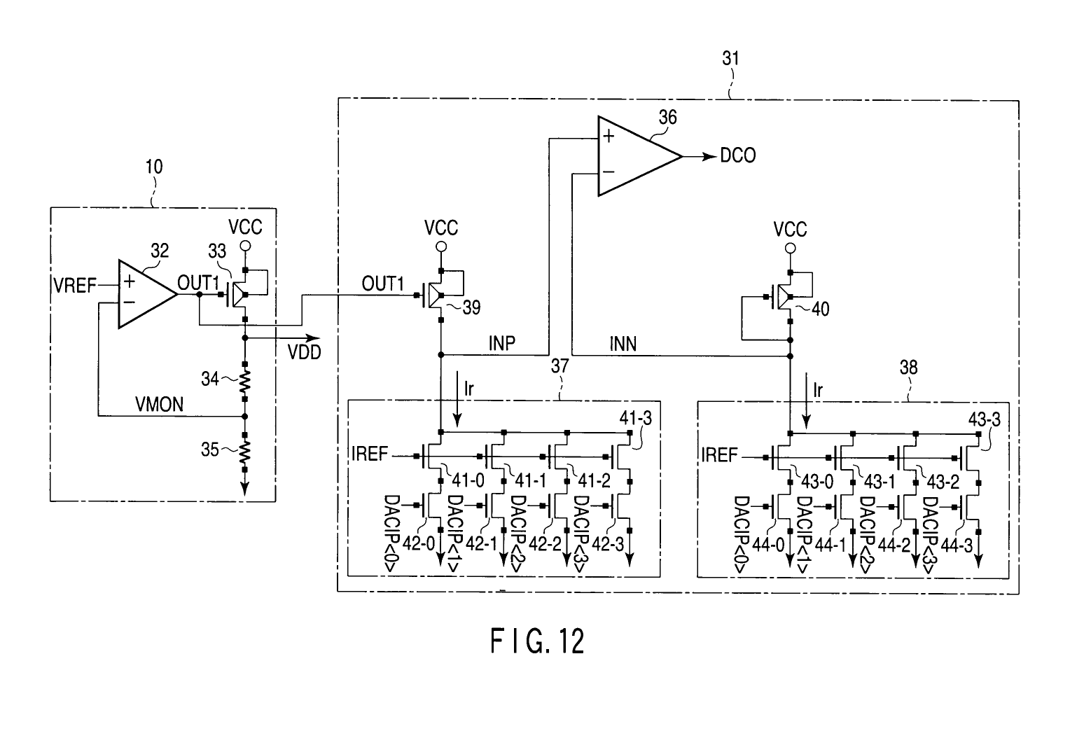

Now, the configuration of the detector 31 will be described in detail with reference to FIG. 12. FIG. 12 is a circuit diagram of the voltage generator 10 and the detector 31.

As shown in FIG. 12, roughly speaking, the detector 31 includes an operational amplifier 36, a first detector 37 and a second detector 38, and p-channel MOS transistors 39 and 40.

A source of the MOS transistor 39 is connected to the power supply voltage Vcc. A gate of the MOS transistor 39 is connected to the node OUT1.

The first detector 37 includes n-channel MOS transistor 41-0 to 41-3 and 42-0 to 42-3. Gates of the MOS transistors 41-0 to 41-3 are connected together, and a current IREF is supplied to the gates. Furthermore, drains of the MOS transistors 41-0 to 41-3 are connected together and to a drain of the MOS transistor 39.

The MOS transistors 42-0 to 42-3 are provided in association with the MOS transistors 41-0 to 41-3. That is, drains of the MOS transistors 42-0 to 42-3 are connected to sources of the MOS transistors 41-0 to 41-3, respectively. Sources of the MOS transistors 42-0 to 42-3 are grounded. Signals DACIP<0> to DACIP<3> are input to gates of the MOS transistors 42-0 to 42-3, respectively. The signals DACIP<0> to DACIP<3> may be provided, for example, by a control circuit (not shown in the drawings) or by an external apparatus. The MOS transistors 41-0 to 41-3 are hereinafter collectively referred to as the MOS transistors 41 if the MOS transistors 41-0 to 41-3 are not distinguished from one another. The MOS transistors 42-0 to 42-3 are hereinafter collectively referred to as the MOS transistors 42 if the MOS transistors 42-0 to 42-3 are not distinguished from one another.

A source of the MOS transistor 40 is connected to the power supply voltage Vcc. A gate and a drain of the MOS transistor 40 are connected together. The size of the MOS transistor 40 is the same as that of, for example, the MOS transistor 39. That is, the gate width of the MOS transistor 40 is the same as that of the MOS transistor 39.

The second detector 38 includes n-channel MOS transistors 43-0 to 43-3 and 44-0 to 44-3. Gates of the MOS transistors 43-0 to 43-3 are connected together, and a current IREF is supplied to the gates. Furthermore, drains of the MOS transistors 43-0 to 43-3 are also connected together and to the drain of the MOS transistor 40. The size of the MOS transistor 43 is the same as that of, for example, the MOS transistor 41. That is, the gate width of the MOS transistor 43 is the same as that of the MOS transistor 41.

The MOS transistors 44-0 to 44-3 are provided in association with the MOS transistors 43-0 to 43-3. That is, drains of the MOS transistors 44-0 to 44-3 are connected to sources of the MOS transistors 43-0 to 43-3, respectively. Sources of the MOS transistors 44-0 to 44-3 are grounded. The signals DACIP<0> to DACIP<3> are input to gates of the MOS transistors 44-0 to 44-3, respectively. The size of the MOS transistor 44 is the same as that of, for example, the MOS transistor 42. That is, the gate width of the MOS transistor 44 is the same as that of the MOS transistor 42. The MOS transistors 43-0 to 43-3 are hereinafter collectively referred to as the MOS transistors 43 if the MOS transistors 43-0 to 43-3 are not distinguished from one another. The MOS transistors 44-0 to 44-3 are hereinafter collectively referred to as the MOS transistors 44 if the MOS transistors 44-0 to 44-3 are not distinguished from one another.

The operational amplifier 36 compares the potential INP of the connection node between the drain of the MOS transistor 39 and the drain of the MOS transistor 41 with the potential INN of the connection node between the drain of the MOS transistor 40 and the drain of the MOS transistor 43. The operational amplifier 36 then outputs the result of the comparison as a signal DCO.

As in the above-described configuration, the MOS transistor 39 receives the potential of the node OUT1 to copy the current flowing through the MOS transistor 33, to the MOS transistor 39. Furthermore, the first detector 37 serving as a constant current source is connected to the drain of the MOS transistor 39. Additionally, the MOS transistor 39, the first detector 37, the MOS transistor 40, and the second detector 38 are used to compare the current of the first detector with the current of the second detector, the MOS transistor 39 having the same size as that of the MOS transistor 40, the MOS transistor 40 functioning as a current source. Therefore, the amount of a current required to charge the bit line BL can be detected.

### <Test Operation>

The current detection using the above-described detector 31 can be performed during testing of the NAND flash memory 1. The method of the current detection will be described below.

The gate widths of the MOS transistors 33 and 40 are defined as Wp2 and Wp3, respectively. The MOS transistors 39 and 40 are configured to have the same gate width. Thus, the peak current in the voltage generator 10 is (Wp2/Wp3) times as large as a current Ir (supplied by the MOS transistors 41 and 43) depending on the constant current IREF. Furthermore, when the number of constant current generators 10 is defined as (n) ((n) is a natural number equal to or larger than 1), the detector 31 can detect the flow of a peak current (Ir*(Wp2/Wp3)*n). If a current the amount of which is larger than this value flows, the potential of the node INP is higher than that of the node INN. The output signal DCO from the operational amplifier 36 changes from an “H” level to an “L” level.

As described in the first embodiment, the peak current value during bit line charging increases consistently with the ramp rate (rising speed) of the potential of the signal BLC. The ramp rate can be controlled by the signal DAC described with reference to FIG. 4. More specifically, for example, if the peak current value is large, the signal DAC is controlled to reduce the number of MOS transistors 27 to be turned on and thus the ramp rate.

As described above, the detector 31 allows determination of whether or not the peak current is larger than the set value. The result can be output though the signal DCO from the operational amplifier 36. Furthermore, the signals DACIP<0> to DACIP<3> can be used to set the magnitude of the set value.

### <Effects>

As described above, the NAND flash memory according to the second embodiment not only exerts the effects described in the first embodiment but also allows the test operation to be simplified. This effect will be described below.

The capacitance of the bit line BL (a capacitance Cp in FIG. 11) varies among chips (this also applies to a parasitic resistance Rp). Thus, the peak current during bit line charging varies among the chips. Furthermore, the gate capacitance of a MOS transistor 7 and the wiring and parasitic capacitances of interconnection through which the signal BLC is transmitted vary among the chips. Consequently, the value of the peak current may differ from a designed one. Furthermore, if the current consumption of the chip itself is measured, the total current value is measured which involves not only the current consumed to charge the bit line but also the current consumed by the other peripheral circuits. Therefore, the current consumption required to charge the bit line cannot be accurately measured by this method.

In this regard, the configuration according to the present embodiment monitors the current flowing through the voltage generator 10, configured to supply the power supply voltage to the sense amplifier 3. More specifically, the current described above is extracted by the MOS transistor 39 which configures a current mirror circuit with the MOS transistor 33 supplying a current to the output node of the power supply, and the current is compared with the set value. This eliminates the need for direct external monitoring of the current, and allows the current to be detected by a simple configuration. Furthermore, this current actually flows through the bit line BL during charging and can thus be accurately detected.

The signal DCO can be used for monitoring to determine whether or not the current flowing through the bit line BL during charging exceeds the set value. Based on the monitoring result, the bit line driver 5 can optimize the number of MOS transistors 28 to be turned on. That is, the signal DAC can be used to trim the peak current, thus simplifying the test operation.

As described above, the semiconductor memory devices according to the first and second embodiments includes the memory cell MT capable of holding data; the bit line BL configured to transfer data read from the memory cell MT and/or data to be written to the memory cell MT; the sense amplifier 3 configured to charge the bit line BL during a data read and a data write; the first MOS transistor 7 configured to connect the bit line BL and the sense amplifier 3 together; and the current source circuit 11 configured to supply a constant current to the gate of the first MOS transistor 7 to charge the gate during the data write and the data read. Furthermore, the constant current supplied by the current source circuit 11 may offer temperature characteristics opposite to those of the current supply capability of the first MOS transistor 7. This enables suppression of a variation in peak current depending on the temperature during bit line charging. Therefore, the peak current can be reduced.

In the above-described embodiments, the drain current of the MOS transistor 7 has negative temperature characteristics. However, if the drain current has positive temperature characteristics, the current Io (or IREF) may be provided with negative temperature characteristics. The temperature characteristics of the current Io depend on the current IREF, which can be generated by, for example, a band gap reference circuit. The temperature characteristics of the current IREF can thus be appropriately set by controlling the resistance value of the band gap reference circuit. Furthermore, in the current mirror circuits shown in FIG. 4 and FIG. 12, the MOS transistors need not necessarily have the same size but may be appropriately configured to have different sizes.

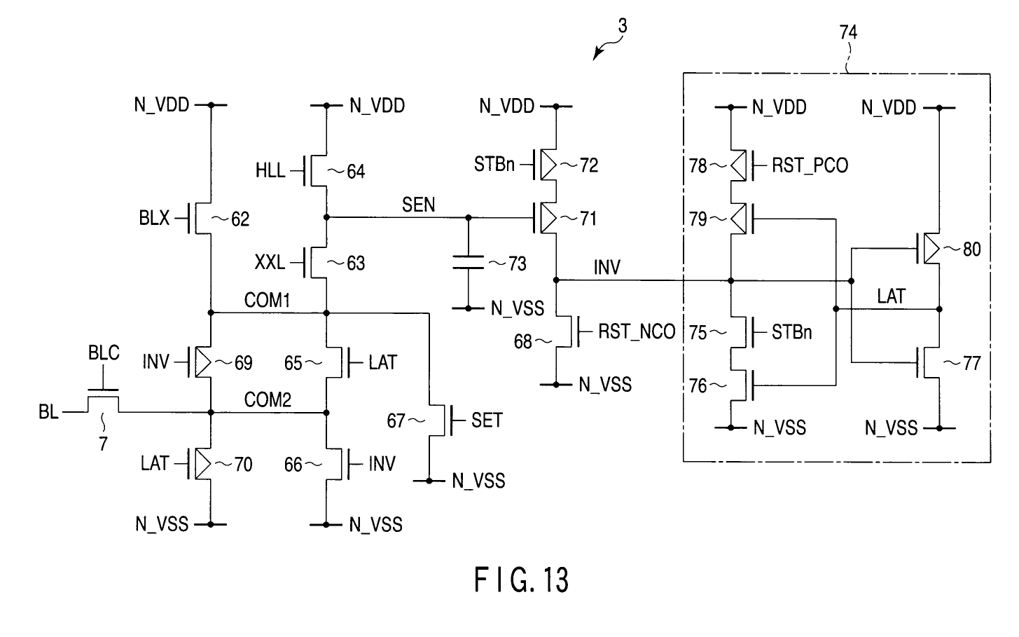

Furthermore, in the above-described embodiments, the constant current circuit 11 and the sense amplifier 3 are provided with the power supply voltage by the same voltage generator 10. However, the constant current circuit 11 and the sense amplifier 3 may be provided with the power supply voltage by different voltage generators 10. Even in this case, the current detected by the detector 31 flows through the voltage generator 10, configured to supply the power supply voltage to the sense amplifier 3. An example of the configuration of the sense amplifier 3 will be described with reference to FIG. 13. FIG. 13 is a circuit diagram of the sense amplifier 3 (and MOS transistor 7).

As shown in FIG. 13, the sense amplifier 3 includes n-channel MOS transistors 62 to 68, p-channel MOS transistors 69 to 72, a capacitor element 73, and a latch circuit 74.

One end of a current path of the MOS transistor 7 is connected to the bit line BL via the current path of the MOS transistor 8 (not shown in the drawings). The other end of the current path of the MOS transistor 7 is connected to a node COM2 in the sense amplifier 3. The signal BLC is applied to a gate of the MOS transistor 7.

One end of a current path of the MOS transistor 70 is connected to the node COM2. The other end of the current path of the MOS transistor 70 is connected to a node N_VSS to which a voltage VSS (for example, 0 V) is applied. A gate of the MOS transistor 70 is connected to a node LAT. One end of a current path of the MOS transistor 66 is connected to the node COM2. The other end of the current path of the MOS transistor 66 is connected to the node N_VSS. A gate of the MOS transistor 66 is connected to a node INV. One end of the current path of the MOS transistor 69 is connected to the node COM2. The other end of the current path of the MOS transistor 69 is connected to a node COM1. A gate of the MOS transistor 69 is connected to the node INV. One end of a current path of the MOS transistor 65 is connected to the node COM2. The other end of the current path of the MOS transistor 65 is connected to the node COM1. A gate of the MOS transistor 65 is connected to the node LAT. One end of a current path of the MOS transistor 67 is connected to the node COM1. The other end of the current path of the MOS transistor 67 is connected to the node N_VSS. A signal SET is input to a gate of the MOS transistor 67. One end of a current path of the MOS transistor 62 is connected to a node N_VDD. The other end of the current path of the MOS transistor 62 is connected to the node COM1. A signal BLX is input to a gate of the MOS transistor 62. The node N_VDD is connected to the connection node between the MOS transistor 33 and resistance element 34 in the voltage generator 10. A voltage VDD is applied to the node N_VDD. One end of a current path of the MOS transistor 63 is connected to a node SEN. The other end of the current path of the MOS transistor 63 is connected to the node COM1. A signal XXL is input to a gate of the MOS transistor 63. One end of a current path of the MOS transistor 64 is connected to the node N_VDD. The other end of the current path of the MOS transistor 64 is connected to the node SEN. A signal HLL is input to a gate of the MOS transistor 64. One electrode of a capacitor element 73 is connected to the node SEN. The other end of the capacitor 73 is connected to the node N_VSS. One end of a current path of the MOS transistor 68 is connected to the node INV. The other end of the current path of the MOS transistor 68 is connected to the node N_VSS. A signal RST_NCO is input to a gate of the MOS transistor 68. One end of a current path of the MOS transistor 71 is connected to the node INV. A gate of the MOS transistor 71 is connected to the node SEN. One end of a current path of the MOS transistor 72 is connected to the node N_VDD. The other end of the current path of the MOS transistor 72 is connected to the other end of the current path of the MOS transistor 71. A signal STBn is input to a gate of the MOS transistor 72.

The latch circuit 74 latches data at the node INV, the connection node between the MOS transistors 68 and 71. That is, the latch circuit 74 includes n-channel MOS transistors 75 to 77 and p-channel MOS transistors 78 to 80.

One end of a current path of the MOS transistor 75 is connected to the node INV. The signal STBn is input to a gate of the MOS transistor 75. One end of a current path of the MOS transistor 76 is connected to the node N_VSS. The other end of the current path of the MOS transistor 76 is connected to the other end of the MOS transistor 75. A gate of the MOS transistor 76 is connected to the node LAT. One end of a current path of the MOS transistor 79 is connected to the node INV. A gate of the MOS transistor 79 is connected to the node LAT. One end of a current path of the MOS transistor 78 is connected to the node N_VDD. The other end of the current path of the MOS transistor 78 is connected to the other end of the MOS transistor 79. A signal RST_PCO is input to a gate of the MOS transistor 78. One end of a current path of the MOS transistor 77 is connected to the node N_VSS. The other end of the current path of the MOS transistor 77 is connected to the node LAT. A gate of the MOS transistor 77 is connected to the node INV. One end of a current path of the MOS transistor 80 is connected to the node N_VDD. The other end of the current path of the MOS transistor 80 is connected to the node LAT. A gate of the MOS transistor 80 is connected to the node INV.

For a reset operation, the above-described signals SET and RST_NCO can be set to “H”. This allows the nodes COM1 and INV to be set to an “L” level (0 V), while allowing the node LAT to be set to the “H” level (VDD). On the other hand, for a normal operation, the above-described signals SET and RST_NCO are set to the “L” level to turn off the MOS transistors 67 and 68. Furthermore, for a reset operation, the signal RST_PCO can be set to “H”. For a normal operation, the signal RST_PCO is set to the “L” level.

In the above-described configuration, for a data write, write data is provided to the latch circuit 74. In the sense amplifier 3 corresponding to the selected bit line, the node INV is set to the “H” level, and the node LAT is set to the “L” level. Thus, the MOS transistors 65 and 69 are turned off. The MOS transistors 66 and 70 are turned on. The selected bit line is provided with 0 V. In the sense amplifier 3 corresponding to the unselected bit line, the node INV is set to the “L” level, and the node LAT is set to the “H” level. Thus, the MOS transistors 66 and 70 are turned off. The MOS transistors 65 and 69 are turned on. As a result, the MOS transistor 62 charges the selected bit line up to VDD.

For a data read, first, the MOS transistor 62 charges the bit line BL up to VDD via the current paths of the MOS transistors 65 and 69 and the nodes COM1 and COM2. Furthermore, the MOS transistor 64 charges the capacitor element 73 to increase the potential of the node SEN.

When the selected cell is turned on, the potential of the node SEN decreases to turn on the MOS transistor 71. The node INV is set to the “H” level, and the node LAT is set to the “L” level. Then, the MOS transistors 66 and 70 are turned on to fix the bit line BL to 0 V. On the other hand, when the selected sell is turned off, the MOS transistor 71 is tuned off with the potential of the node SEN prevented from decreasing. Thus, the node INV remains at the “L” level. The node LAT remains at the “H” level.

The sense amplifier 3 may be configured as follows. All the voltage values described in the above-described embodiments, including those for the sense amplifier 3, are only illustrative. The embodiments are not limited to the above-described values.

Moreover, the above-described embodiments, the semiconductor memory device is a NAND flash memory by way of example. However, the embodiments are applicable to any other flash memory such as an NOR flash memory. The present embodiments are also applicable to a three-dimensional stacked NAND flash memory in which NAND strings are stacked perpendicularly to a semiconductor substrate surface. Such a NAND flash memory is disclosed in, for example, Jpn. Pat. Appln. KOKAI Publication No. 2007-266143, the entire contents (all pages) of this reference being incorporated herein by reference. Moreover, the present embodiments are applicable not only to flash memories but also to ReRAMs (Resistance Random Access Memories). In a ReRAM, each memory cell is formed of a variable resistance element and a diode. Of course, the present embodiments are applicable to other semiconductor memories in general.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell capable of holding data;
a bit line which transfers data read from the memory cell and/or data to be written to the memory cell;
a sense amplifier which charges the bit line during a data read and a data write;
a first MOS transistor which connects the bit line and the sense amplifier together; and
a current source circuit which supplies a constant current to a gate of the first MOS transistor to charge the gate during a data write and/or a data read.

2. The device according to claim 1, wherein the constant current has a temperature characteristic opposite to that of a current supply capability of the first MOS transistor.

3. The device according to claim 1, wherein the constant current has a temperature characteristic opposite to that of a drain current of the first MOS transistor.

4. The device according to claim 1, wherein the current source circuit includes:
a second MOS transistor with a gate to which a constant current with a temperature characteristic opposite to that of a current supply capability of the first MOS transistor is provided;
a first current mirror circuit including a third MOS transistor with a current path one end of which is connected to one end of a current path of the second MOS transistor, and a fourth MOS transistor with a gate connected to a gate of the third MOS transistor;
a second current mirror circuit including a fifth MOS transistor with a current path one end of which is connected to one end of a current path of the fourth MOS transistor, and a plurality of sixth MOS transistors with a gate connected to a gate of the fifth MOS transistor; and
a third current mirror circuit including a seventh MOS transistor with a current path one end of which is connected to one end of a current path of each of the sixth MOS transistors, and an eighth MOS transistor including a gate connected to a gate of the seventh MOS transistor and a current path one end of which is connected to a gate of the first MOS transistor.

5. The device according to claim 4, wherein the current source circuit further includes a plurality of ninth MOS transistors connected to other ends of the sixth MOS transistors, and
the number of the ninth MOS transistors to be turned on is variable.

6. The device according to claim 4, wherein the current source circuit includes:
a ninth MOS transistor with a current path one end of which is connected to the other end of the current path of the second MOS transistor; and
a tenth MOS transistor with a current path one end of which is connected to the other end of the current path of the fifth MOS transistor;
wherein a control signal to activate the current source circuit is input to gates of the ninth and tenth MOS transistors.

7. The device according to claim 1, wherein the memory cell is connected to the bit line via a current path of a selection transistor,
in a data write, the sense amplifier applies a first voltage to a selected bit line, and applies a second voltage higher than the first voltage, to an unselected bit line, and
the selection transistor is turned on when the first voltage is applied to the bit line, and is cut off when the second voltage is applied to the bit line.

8. The device according to claim 1, further comprising:
a voltage generator which generates a power supply voltage for the sense amplifier; and
a detector which detects a current of the bit line,
wherein the voltage generator includes a second MOS transistor which supplies a current to an output node outputting the power supply voltage, and
the detector compares a set value with a drain current of a third MOS transistor forming a current mirror circuit together with the second MOS transistor.

9. The device according to claim 8, wherein a value of the constant current supplied by the current source circuit is set in accordance with a detection result from the detector.

10. The device according to claim 8, wherein the set value is variable.

11. A semiconductor memory device comprising:
a memory cell capable of holding data;
a bit line which is connected to the memory cell to transfer the data;
a sense amplifier which charges the bit line;
a first MOS transistor which connects the bit line and the sense amplifier together; and
a current source circuit which supplies a current with a temperature characteristic opposite to that of a drain current of the first MOS transistor, to charge a gate of the first MOS transistor.

12. The device according to claim 11, wherein the current source circuit includes:
a second MOS transistor with a gate to which a constant current with a temperature characteristic opposite to that of the drain current of the first MOS transistor is supplied;
a first current mirror circuit including a third MOS transistor with a current path one end of which is connected to one end of a current path of the second MOS transistor, and a fourth MOS transistor with a gate connected to a gate of the third MOS transistor;
a second current mirror circuit including a fifth MOS transistor with a current path one end of which is connected to one end of a current path of the fourth MOS transistor, and a plurality of sixth MOS transistors with a gate connected to a gate of the fifth MOS transistor; and
a third current mirror circuit including a seventh MOS transistor with a current path one end of which is connected to one ends of current paths of the sixth MOS transistors, and an eighth MOS transistor including a gate connected to a gate of the seventh MOS transistor and a current path one end of which is connected to a gate of the first MOS transistor.

13. The device according to claim 12, wherein the current source circuit further including a plurality of ninth MOS transistors connected to other ends of the sixth MOS transistors, and
the number of the ninth MOS transistors to be turned on is variable.

14. The device according to claim 12, wherein the current source circuit includes:
a ninth MOS transistor with a current path one end of which is connected to other end of the current path of the second MOS transistor; and
a tenth MOS transistor with a current path one end of which is connected to other end of the current path of the fifth MOS transistor;
wherein a control signal to activate the current source circuit is input to gates of the ninth and tenth MOS transistors.

15. The device according to claim 11, wherein the memory cell is connected to the bit line via a current path of a selection transistor,
in a data write, the sense amplifier applies a first voltage to a selected bit line, and applies a second voltage higher than the first voltage, to an unselected bit line, and
the selection transistor is turned on when the first voltage is applied to the bit line, and is cut off when the second voltage is applied to the bit line.

16. The device according to claim 11, further comprising:
a voltage generator which generates a power supply voltage for the sense amplifier; and
a detector which detects a current of the bit line,
wherein the voltage generator includes a second MOS transistor which supplies a current to an output node outputting the power supply voltage, and
the detector compares a set value with a drain current of a third MOS transistor forming a current mirror circuit together with the second MOS transistor.

17. The device according to claim 16, wherein a value of the current supplied by the current source circuit is set in accordance with a detection result from the detector.

18. The device according to claim 16, wherein the set value is variable.
